(19) United States
(12) Patent Application Publication
(10) Pub. No.: US 2025/0220919 A1
(43) Pub. Date: Jul. 3, 2025

(54) SEMICONDUCTOR DEVICE AND METHOD OF MANUFACTURING THE SAME

(71) Applicant: Renesas Electronics Corporation, Tokyo (JP)

(72) Inventor: Tadashi YAMAGUCHI, Tokyo (JP)

(21) Appl. No.: 18/915,721

(22) Filed: Oct. 15, 2024

(30) Foreign Application Priority Data
Dec. 28, 2023 (JP) 2023-223662

(51) Int. Cl. H10B 51/30; H01L 29/66; H01L 29/78

(52) U.S. Cl. CPC H10B 51/30; H10D 30/0415; H10D 30/701

(57) ABSTRACT

Enhancing the performance of semiconductor devices by reducing the operating voltage of a ferroelectric memory equipped with a ferroelectric film. On a semiconductor substrate, forming a laminated body including a paraelectric film, which is an insulating film, and the ferroelectric film made of three or more layers of ferroelectric layers to on the insulating film, and forming a metal film and a gate electrode on the ferroelectric film. By discretely placing impurity particles between the ferroelectric layers that are in contact with each other, the crystallinity of the ferroelectric film is enhanced.

### CROSS-REFERENCE TO RELATED APPLICATIONS

The disclosure of Japanese Patent Application No. 2023-223662 filed on Dec. 28, 2023, including the specification, drawings and abstract is incorporated herein by reference in its entirety.

### BACKGROUND

The present invention relates to semiconductor devices and their manufacturing methods, particularly to semiconductor devices equipped with ferroelectric memory cells and their manufacturing methods.

In recent years, the ferroelectric memory cells using ferroelectric films have been developed as semiconductor memory elements operating at low voltage. The ferroelectric memory cells are nonvolatile memory cells that change between write and erase states by controlling the direction of polarization of the ferroelectric material. Japanese Patent Laid-Open No. 2019-201172 (Patent Document 1) discloses the structure and manufacturing method of the ferroelectric memory cells.

### SUMMARY

Hafnium-based Hf_{0.5}Zr_{0.5}O₂(HZO) is widely known as the ferroelectric film. However, there is a problem that it is difficult to reduce an operating voltage of a ferroelectric memory cell with the existing structure of HZO films.

Other objects and novel features will become apparent from the description of this specification and the accompanying drawings.

The typical ones of the embodiments disclosed in the present application will be briefly described as follows.

A semiconductor device according to one embodiment includes the ferroelectric memory cell equipped with a paraelectric film and a ferroelectric film, which is a laminated body including three or more layers of ferroelectric layers, sequentially provided on a semiconductor substrate.

A method for manufacturing a semiconductor device according to one embodiment involves forming the paraelectric film, a laminated structure, and a metal film in sequence on the semiconductor substrate, followed by a heat treatment. The laminated structure is formed by repeating at least three times the steps of forming an amorphous layer and discretely providing impurity particles on the surface of the amorphous layer. In the heat treatment step, each of the amorphous layers is crystallized in a horizontal direction to form a laminated film of ferroelectric.

According to one embodiment, the performance of the semiconductor device can be improved.

### BRIEF DESCRIPTION OF THE DRAWINGS

FIG. 1 is a cross-sectional view showing a main part of a semiconductor device in a first embodiment.

FIG. 2 is a cross-sectional view of the semiconductor device in the first embodiment.

FIG. 3 is a table showing an operating condition of the semiconductor device in the first embodiment.

FIG. 4 is a cross-sectional view during a manufacturing process of the semiconductor device in the first embodiment.

FIG. 5 is a cross-sectional view during the manufacturing process of the semiconductor device following FIG. 4.

FIG. 6 is a cross-sectional view during the manufacturing process of the semiconductor device following FIG. 5.

FIG. 7 is a cross-sectional view during the manufacturing process of the semiconductor device following FIG. 6.

FIG. 8 is a cross-sectional view during the manufacturing process of the semiconductor device following FIG. 7.

FIG. 9 is a cross-sectional view during the manufacturing process of the semiconductor device following FIG. 8.

FIG. 10 is a cross-sectional view during the manufacturing process of the semiconductor device following FIG. 9.

FIG. 11 is a cross-sectional view during the manufacturing process of the semiconductor device following FIG. 10.

FIG. 12 is a cross-sectional view during the manufacturing process of the semiconductor device following FIG. 11.

FIG. 13 is a cross-sectional view during the manufacturing process of the semiconductor device following FIG. 12.

FIG. 14 is a cross-sectional view during the manufacturing process of the semiconductor device following FIG. 13.

FIG. 15 is a cross-sectional view during the manufacturing process of the semiconductor device following FIG. 14.

FIG. 16 is a perspective view showing the mode of two-dimensional crystallization of an amorphous layer.

FIG. 17 is a cross-sectional view showing the mode of two-dimensional crystallization of the amorphous layer.

FIG. 18 is a cross-sectional view explaining a range of film thickness of the amorphous layer where two-dimensional nucleation predominates.

FIG. 19 is a graph showing a relationship between a radius of a crystal and a driving energy of the crystal.

FIG. 20 a table showing a result of experiments conducted to explore methods for reducing a surface energy σ₂.

FIG. 21 is a schematic diagram showing an arrangement of impurity particles in the first embodiment.

FIG. 22 is a graph showing writing characteristics of the semiconductor device in the first embodiment.

FIG. 23 is a graph showing erasing characteristics of the semiconductor device in the first embodiment.

FIG. 24 is a graph showing a result of X-ray diffraction on a ferroelectric film in the first embodiment.

FIG. 25 is a graph showing a strength of a rectangular body in the ferroelectric film in the first embodiment.

FIG. 26 a flow showing a manufacturing process of a semiconductor device in a second embodiment.

FIG. 27 is a cross-sectional view during the manufacturing process of the semiconductor device in the second embodiment.

FIG. 28 is a flow showing the manufacturing process of the semiconductor device in the third embodiment.

FIG. 29 is a cross-sectional view showing a mode of three-dimensional crystallization of an amorphous layer.

FIG. 30 is a cross-sectional view showing a main part of a semiconductor device in a comparative example.

FIG. 31 is a graph showing writing characteristics of the semiconductor device in the comparative example.

FIG. 32 is a graph showing erasing characteristics of the semiconductor device in the comparative example.

### DETAILED DESCRIPTION

In the following embodiment, when required for convenience, it is divided into plurality of sections or embodiment, but unless otherwise specified, they are not related to each other, and one of them is related to modified example, detailed, supplementary explanation, etc. of a part or all of the other. In addition, in the following embodiments, the number of elements or the like (including the number, the number, the amount, the range, and the like) is not limited to the mentioned number, except the case where it is specified in particular or the case where it is obviously limited to a specific number in principle, and may be equal to or more than the mentioned number or may be equal to or less than the mentioned number.

Furthermore, in the following embodiments, the constituent elements (including element steps and the like) are not necessarily essential except for the case in which they are specifically specified, the case in which they are considered to be obviously essential in principle, and the like. Similarly, in the following embodiments, when referring to the shapes, positional relationships, and the like of components and the like, it is assumed that the shapes and the like are substantially approximate to or similar to the shapes and the like, except for the case in which they are specifically specified and the case in which they are considered to be obvious in principle, and the like. The same applies to the above numerical values and ranges.

Hereinafter, embodiments are described in detail with reference to the drawings. In all the drawings for explaining the embodiments, members having the same functions are denoted by the same reference numerals, and repetitive descriptions thereof are omitted. Furthermore, in the following embodiments, descriptions of the same or similar parts will not be repeated in principle except when particularly necessary.

Additionally, in the following, the direction along the main surface of the semiconductor substrate may be referred to as the planar direction, and the direction perpendicular to the main surface of the semiconductor substrate may be referred to as the thickness direction.

### First Embodiment

### Summary of the First Embodiment

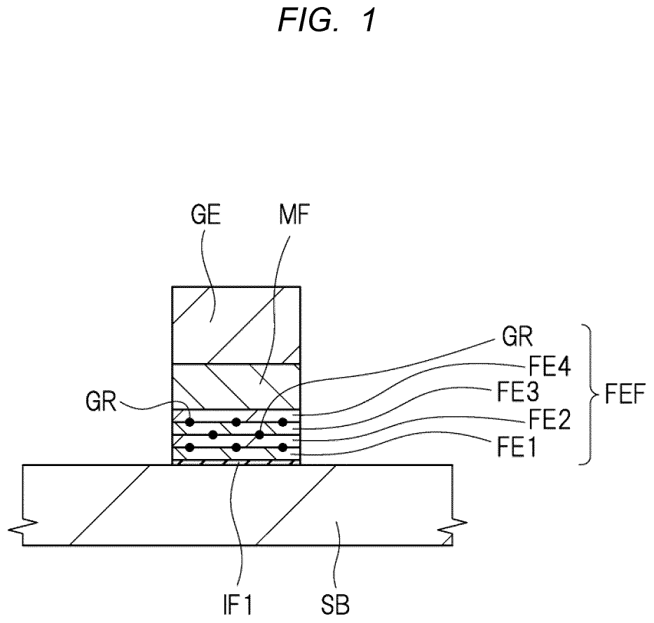

FIG. 1 shows a schematic cross-sectional view of a main part of the semiconductor device of this embodiment. FIG. 1 primarily illustrates the stacked structure between a semiconductor substrate and a gate electrode of a ferroelectric memory cell. As shown in FIG. 1, the semiconductor device of this embodiment has the semiconductor substrate SB. The semiconductor substrate SB includes a first main surface, which is an upper surface, and a second main surface, which is the opposite side of the first main surface. On the first main surface of the semiconductor substrate SB, an insulating film IF1, which is a paraelectric film, a ferroelectric film FEF including a plurality of ferroelectric layers, a metal film MF, and the gate electrode GE are sequentially stacked.

The ferroelectric film FEF includes the plurality of ferroelectric layers FE1, FE2, FE3, and FE4, which are stacked in order from the semiconductor substrate SB upwards. That is, the ferroelectric film FEF includes a stacked layer includes three or more ferroelectric layers stacked in order from the side of the semiconductor substrate SB. Between the ferroelectric layers FE1 and FE2, between the ferroelectric layers FE2 and FE3, and between the ferroelectric layers FE3 and FE4, impurity particles GR are discretely present.

Below, it will be explained how having three or more ferroelectric layers in the ferroelectric film enhances the crystallinity of the ferroelectric film of the ferroelectric memory cell, thereby reducing an operating voltage of the ferroelectric memory cell.

### (Semiconductor Device Structure)

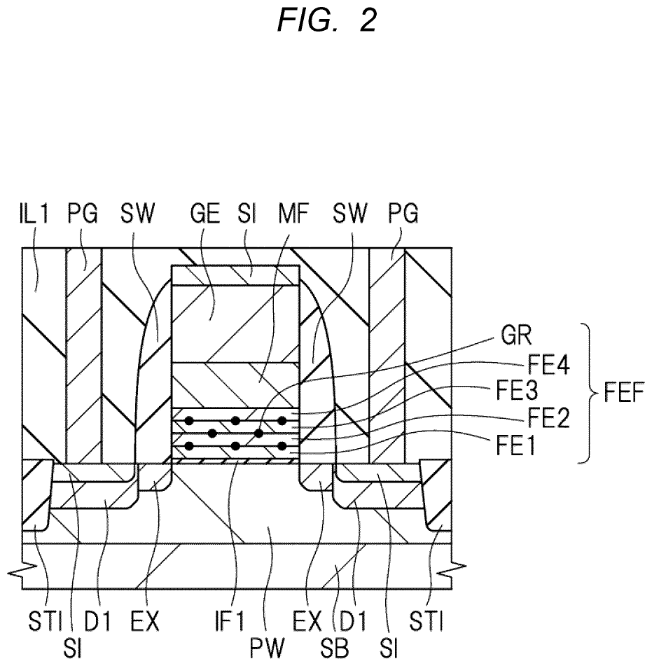

FIG. 2 shows a specific structure of the ferroelectric memory cell, which is the semiconductor device of this embodiment. The ferroelectric memory cell shown in FIG. 2 has the semiconductor substrate SB with the first main surface and the second main surface. The semiconductor substrate SB is made of, for example, p-type monocrystalline silicon (Si) with a specific electrical resistance of about 1 to 10 Ω·cm. A p-type well region PW reaching a predetermined depth from the first main surface side towards the second main surface side is formed in the semiconductor substrate SB. On the first main surface of the semiconductor substrate SB, a plurality of element isolation regions STI reaching a predetermined depth towards the second main surface side are formed. The plurality of element isolation regions STI are formed by embedding the insulating film, such as a silicon oxide film, in grooves formed in the semiconductor substrate SB.

In this embodiment, as the ferroelectric memory cell, a memory cell called an MFIS (Metal Ferroelectric Insulator Semiconductor) structure, which applies the ferroelectric film FEF to a transistor structure, is exemplified.

On the semiconductor substrate SB including the well region PW, the insulating film IF1 is formed as the paraelectric film. The insulating film IF1 is, for example, a silicon oxide (SiO₂) film or a silicon oxynitride (Si₃NO₄) film, having a thickness of 2 nm or less. The insulating film IF1 is a film provided for a purpose of stabilizing an interface between the semiconductor substrate SB and the ferroelectric film FEF, or to prevent electrons from entering the ferroelectric film FEF from the semiconductor substrate SB when a voltage is applied to the gate electrode GE during an operation of the ferroelectric memory cell.

On the insulating film IF1, the ferroelectric film FEF is formed. The ferroelectric film FEF has impurity particles GR existing between the ferroelectric layers FE1, FE2, FE3, and FE4, which are stacked in order from a side of the semiconductor substrate SB.

Each of the ferroelectric layers FE1 to FE4 are made of a metal oxide film and is a high dielectric constant layer with a higher dielectric constant than, for example, a silicon nitride film. Furthermore, a thickness of each of the ferroelectric layers FE1 to FE4 is, for example, 0.5 nm or more and 2 nm or less. A thickness of the ferroelectric film FEF is, for example, 6 nm or more and 20 nm or less.

Moreover, each of the ferroelectric layers FE1 to FE4 is an insulating layer composes materials that exhibits dielectric polarization when an electric field is applied and retains polarization even after the electric field is removed, i.e., a ferroelectric. That is, even when no electric field is applied, polarization remains in the ferroelectric layers FE1 to FE4 (ferroelectric film FEF). Ferroelectric is material in which electric dipoles are aligned even without an external electric field, and a direction of the dipoles can be changed by an electric field.

Furthermore, each of the ferroelectric layers FE1 to FE4 needs to be a tetragonal crystal. In other words, films primarily include crystals other than the tetragonal crystal is the paraelectric film. Therefore, in the ferroelectric memory cell, it is necessary to form the crystals including the ferroelectric layers FE1 to FE4 as much as possible in tetragonal to increase a residual polarization of the ferroelectric film FEF, improve a performance as a ferroelectric, and reduce a driving power of the ferroelectric memory cell. That is, it is necessary to enhance a crystallinity of the ferroelectric layers FE1 to FE4.

Each of the ferroelectric layers FE1 to FE4 is the insulating film (HZO film) made of materials containing a metal oxide and a first element. The metal oxide is, for example, hafnium oxide (HfO) or gallium oxide (GaO). The first element is zirconium (Zr), silicon (Si), germanium (Ge), yttrium (Y), lanthanum (La), or ytterbium (Yb).

Between the ferroelectric layers FE1 and FE2, as part of the ferroelectric film FEF, the impurity particles GR are formed. As described later, the impurity particles GR function as nuclei for crystal growth from an amorphous state to a tetragonal crystal of the ferroelectric layers FE1 to FE4 during a manufacturing process of the ferroelectric film FEF. Therefore, the impurity particles GR are separated from each other and are discretely arranged. In other words, the impurity particles GR are not continuously formed films like the ferroelectric layers FE1 to FE4 but are discontinuously arranged in the direction along the first main surface of the semiconductor substrate SB. If each of the impurity particles GR were connected to form a film, their function as crystal nuclei for the impurity particles GR would be reduced.

The impurity particles GR contain a second element different from both oxygen and the first element. The second element is silicon (Si), aluminum (Al), carbon (C), nitrogen (N), hydrogen (H), or oxygen (O). Specifically, the impurity particles GR are either aluminum nitride, silicon, aluminum, carbon, nitrogen, hydrogen, oxygen, or a mixture or compound thereof. In this embodiment, each of the impurity particles GR include, for example, of one atom, a compound, or an aggregate of 2 to 4 atoms. Here, the case where the impurity particles GR are particles of AlN (aluminum nitride) is mainly described.

Moreover, the impurity particles GR, during the manufacturing process of the ferroelectric film FEF, may bond with materials contained in the ferroelectric layers FE1, FE2, FE3, or FE4 near an interface between an upper and a lower ferroelectric layers. That is, the impurity particles GR may ultimately be compounds bonded with aluminum nitride, silicon, aluminum, carbon, nitrogen, hydrogen, or oxygen, and hafnium or the aforementioned first element.

A surface density of the impurity particles GR is within a range of 1×10¹²/cm² to 1×10¹³/cm². Furthermore, a volume density of the impurity particles GR is within a range of 1×10¹⁸/cm³ to 1×10²¹/cm³. An average distance between the impurity particles GR in a plan view is between 2.5 nm and 11 nm.

The metal film MF is formed on the ferroelectric film FEF. The metal film MF is, for example, a conductive film formed of a titanium nitride film, a tantalum nitride film, or a tungsten film. A thickness of the metal film MF is, for example, between 2 nm and 10 nm. The metal film MF serves as a cap film provided during the manufacturing process of the ferroelectric film FEF to apply stress to the ferroelectric layers FE1 to FE4 and to control the orientation of the crystals of each of the ferroelectric layers FE1 to FE4. Therefore, after a formation of the ferroelectric film FEF, if each of the ferroelectric layers FE1 to FE4 can exist as orthorhombic crystals, the metal film MF may be removed. However, removing the metal film MF may cause variations in an orientation of the crystals of each of the ferroelectric layers FE1 to FE4, so it is preferable to leave the metal film MF. If the metal film MF is left, it can also function as part of the gate electrode GE mentioned later.

The gate electrode GE is formed on the metal film MF. The gate electrode GE is, for example, a conductive film made of polysilicon film into which n-type impurities have been introduced. Instead of the polysilicon film, metal films such as titanium nitride film, aluminum film, or tungsten film, or laminated films appropriately laminated from these, may also be used as materials constituting the gate electrode GE.

A sidewall spacer SW is formed on sides of the gate electrode GE. The sidewall spacer SW is formed of, for example, a laminated film of a silicon oxide film and a silicon nitride film.

In the well region PW below the sidewall spacer SW, an extension region EX, which is a low concentration n-type impurity region, is formed. Also, in the well region PW aligned with the sidewall spacer SW, a diffusion region D1, which is a higher concentration n-type impurity region than the extension region EX, is formed. The extension region EX and the diffusion region D1 are interconnected, each constituting part of a source region or part of a drain region of the ferroelectric memory cell.

The ferroelectric memory cell comprises at least the insulating film IF1, the ferroelectric film FEF, and the gate electrode GE, and a pair of diffusion regions D1 constituting part of the source region or part of the drain region.

On the gate electrode GE and the diffusion region D1, a silicide layer SI including, for example, cobalt silicide (CoSi2), nickel silicide (NiSi), or nickel platinum silicide (NiPtSi) is formed. The silicide layer SI is primarily formed to reduce the contact resistance with a plug PG mentioned later.

An interlayer insulating film IL1 is formed on the ferroelectric memory cell. The interlayer insulating film IL1 is, for example, a silicon oxide film. In the interlayer insulating film IL1, a plurality of contact holes are formed, and within these contact holes, a plurality of plugs PG are formed. The plug PG includes a barrier metal film made of, for example, a titanium film, a titanium nitride film, or a laminated film of these, and a conductive film primarily includes tungsten. The plug PG is electrically connected to the diffusion region D1 through the silicide layer SI. Although not shown, there are also plugs PG in the interlayer insulating film IL1 that are electrically connected to the gate electrode GE.

Furthermore, although not shown, a plurality of wirings are formed on the plug PG. For example, another interlayer insulating film is formed on the interlayer insulating film IL1, and grooves for the wirings are formed in this interlayer insulating film. Then, by embedding a conductive film mainly includes copper into these grooves for the wirings, the first layer of the wiring connected to the plug PG is formed.

### (Operation of Ferroelectric Memory Cell)

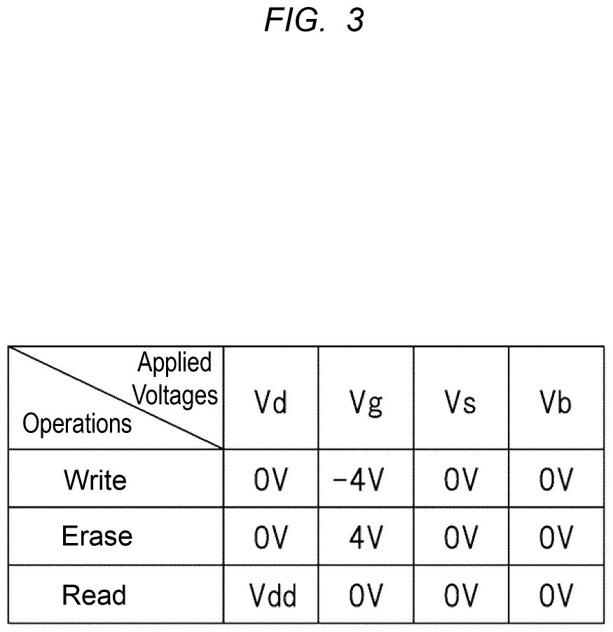

Next, an example of an operation of the ferroelectric memory cell will be described with reference to FIG. 3.

FIG. 3 is a table showing an example of the applied voltages to various parts of a selected memory cell during “write,” “erase,” and “read” operations. The table in FIG. 3 lists the voltages applied to each part during each of these operations. Specifically, the table includes the voltage Vd applied to the drain region (one diffusion region D1) of the ferroelectric memory cell shown in FIG. 2, a voltage Vg applied to the gate electrode GE, the voltage Vs applied to the source region (the other diffusion region D1), and a voltage Vb applied to the well region PW. Note that what is shown in the table of FIG. 3 is a suitable example of the voltage application condition, and is not limited to this, and can be variously changed as necessary.

In this embodiment, “writing” is defined as the state where the polarization of the ferroelectric film FEF is upward, resulting in a relatively high threshold voltage of the ferroelectric memory cell. Conversely, “erasing” is defined as the state where the polarization of the ferroelectric film FEF is downward, resulting in a relatively low threshold voltage of the ferroelectric memory cell.

A write operation is performed by applying a negative voltage to the gate electrode GE. That is, voltages such as those shown in the “write” column of FIG. 3 are applied to each part of the selected memory cell being written to. As a result, the polarization of the ferroelectric film FEF becomes upward, the threshold voltage of the ferroelectric memory cell increases, and the ferroelectric film FEF enters the write state.

An erase operation is performed by applying a positive voltage to the gate electrode GE. That is, voltages such as those shown in the “erase” column of FIG. 3 are applied to each part of the selected memory cell being erased. This causes the polarization of the ferroelectric film FEF to become downward, the threshold voltage of the ferroelectric memory cell decreases, and the ferroelectric film FEF enters the erase state.

During a read operation, voltages such as those shown in the “read” column of FIG. 3 are applied to each part of the selected memory cell being read. By setting the voltage Vg applied to the gate electrode GE to a value between the threshold voltage of the ferroelectric film FEF in the write state and the threshold voltage of the ferroelectric film FEF in the erase state, it is possible to distinguish between the write and erase states.

### (Manufacturing Process of Semiconductor Device)

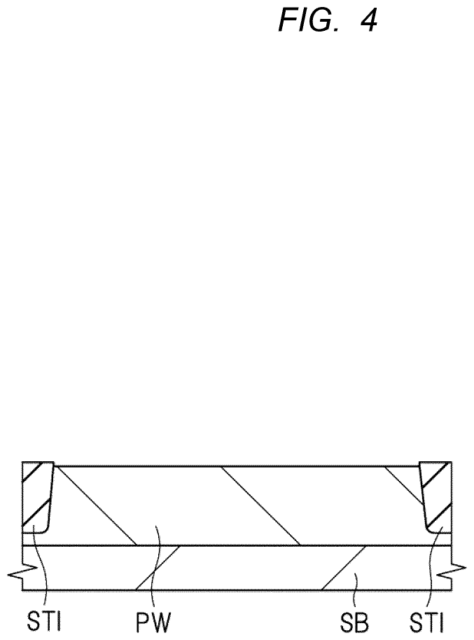

A manufacturing method of the semiconductor device according to the present embodiment is described below using FIGS. 4 to 15. Each of FIGS. 4 to 15 is a cross-sectional view showing the area where the ferroelectric memory cell is formed.

FIG. 4 shows a process of forming the element isolation region STI and the well region PW.

First, the semiconductor substrate SB made of monocrystalline silicon, into which p-type impurities have been introduced, for example, is prepared. Next, a trench is formed in the semiconductor substrate SB using photolithography and etching processes. Then, the insulating film such as a silicon oxide film is formed to fill the trench, and thereafter, the insulating film outside the trench is removed by Chemical Mechanical Polishing (CMP) method, thereby forming the element isolation region STI made of the insulating film remaining in the trench.

Next, the p-type well region PW is formed by introducing impurities into the semiconductor substrate SB using photolithography and ion implantation methods.

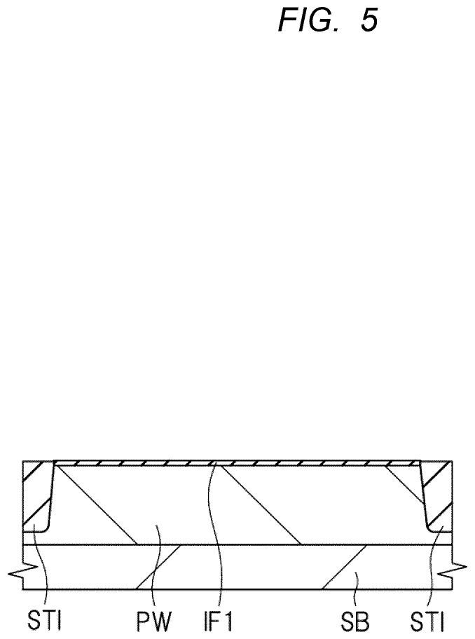

FIG. 5 shows a process of forming the insulating film IF1.

On the semiconductor substrate SB, the insulating film IF1 made of, for example, silicon oxide or silicon oxynitride is formed by performing a heat treatment in an atmosphere containing oxygen, for example. The thickness of the insulating film IF1 is, for example, 1 nm or less.

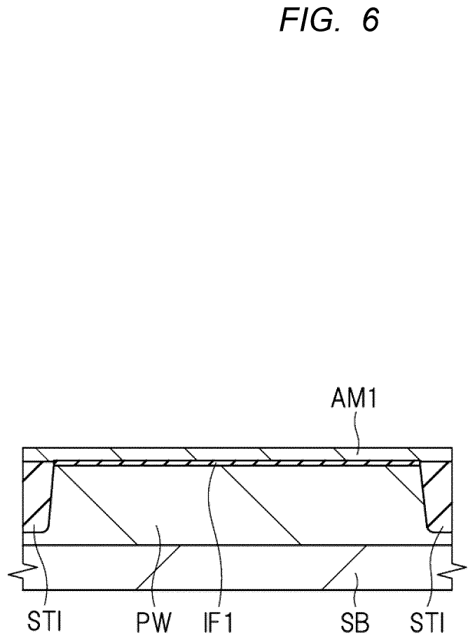

FIG. 6 shows a process of forming an amorphous layer AM1.

On the insulating film IF1, the amorphous layer (amorphous film) AM1 is formed, for example, by Atomic Layer Deposition (ALD) method. A thickness of the amorphous layer AM1 is, for example, from 0.5 nm to 2 nm. The amorphous layer AM1 is a film made of materials containing hafnium (Hf), oxygen (O), and the first element such as zirconium (Zr). Moreover, the first element may be replaced with silicon (Si), germanium (Ge), yttrium (Y), lanthanum (La), or ytterbium (Yb).

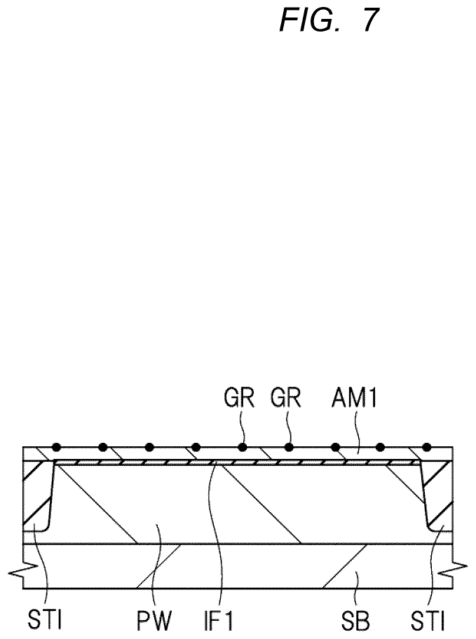

FIG. 7 shows a process of forming the impurity particles GR.

The semiconductor wafer from the ALD apparatus used in the process of forming the amorphous layer AM1 in FIG. 6 is transferred to another apparatus, and the process in FIG. 7 is carried out. In this embodiment, the impurity particles GR are formed on the amorphous layer AM1 by sputtering method. The impurity particles GR are separated from each other. In other words, the impurity particles GR are not formed as a continuous film like the amorphous layer AM1 but are formed discretely. That is, the impurity particles GR do not cover the entire amorphous layer AM1 but are scattered on the amorphous layer AM1. Therefore, part of the amorphous layer AM1 is covered by the impurity particles GR, and other parts of the amorphous layer AM1 are exposed from the impurity particles GR. Also, some of the impurity particles GR are deposited on the upper surface of the amorphous layer AM1, but there is also the impurity particles GR introduced near the upper surface within the amorphous layer AM1. For this reason, in the process of crystallizing the amorphous layer AM1 and others described later, the impurity particles GR function as crystal nuclei.

Furthermore, the impurity particles GR are either aluminum nitride, silicon, aluminum, carbon, nitrogen, hydrogen, oxygen, or any mixture or compound thereof. In this embodiment, the case where the second element is aluminum is exemplarily illustrated for explanation. Here, the impurity particles GR includes aluminum nitride (AlN).

Moreover, although the impurity particles GR can be formed by Chemical Vapor Deposition (CVD) method instead of sputtering, it is preferable to form them separated from each other as mentioned above. Therefore, the formation method of the impurity particles GR is preferably carried out by sputtering. Additionally, the surface density of the impurity particles GR on the upper surface of the amorphous layer AM1 is within the range of 1×10¹²/cm² to 1×10¹³/cm². This allows for precise control of the crystal grain size radius of the impurity particles GR, for example, within a range of 0.1 nm to 1 nm. Here, the surface density of the impurity particles GR is set to, for example, 1×10¹³/cm².

Furthermore, to prevent the impurity particles GR from diffusing too much into the amorphous layer AM1, the above-mentioned sputtering method is preferably performed at a temperature range of 1 degree Celsius or more and 150 degrees Celsius or less.

As mentioned above, the second element constituting the impurity particles GR may be an element other than aluminum, and in such cases, the formation method of the impurity particles GR can also be carried out using ion implantation instead of sputtering. When using the ion implantation method, the dose amount of the impurity particles GR is set within the range of 1×10¹²/cm² to 1×10¹³/cm².

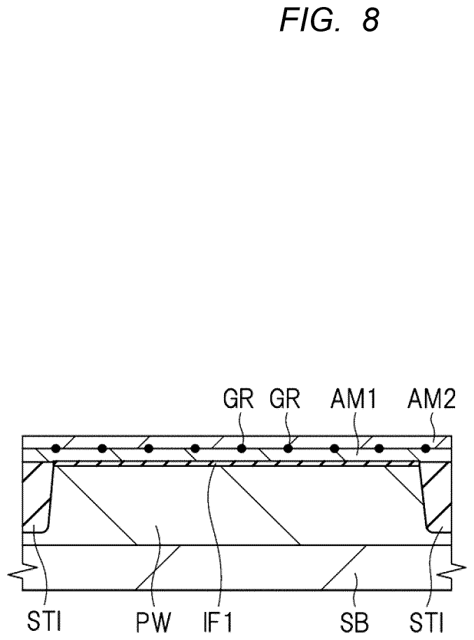

FIG. 8 illustrates a formation process of an amorphous layer AM2.

On top of the impurity particles GR and the amorphous layer AM1, the amorphous layer (amorphous film) AM2 is formed, for example, by ALD method. Through this process, the impurity particles GR are covered by the amorphous layer AM2. A thickness of the amorphous layer AM2 is, for example, from 0.5 nm to 2 nm. The amorphous layer AM2 includes of the same material as the amorphous layer AM1, for example, a film made of materials containing hafnium (Hf), oxygen (O), and zirconium (Zr) as the first element. Moreover, the first element may be silicon (Si), germanium (Ge), yttrium (Y), lanthanum (La), or ytterbium (Yb) instead of zirconium.

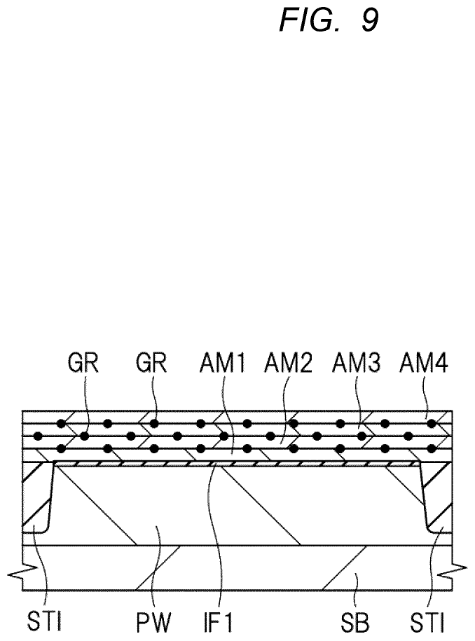

FIG. 9 shows a formation process of amorphous layers AM3 and AM4, and the impurity particles GR.

By repeating the processes described using FIGS. 7 and 8, the impurity particles GR, the amorphous layer AM3, the impurity particles GR, and the amorphous layer AM4 are sequentially formed on top of the amorphous layer AM2. Thus, a laminated structure includes sequentially stacked the amorphous layers AM1, AM2, AM3, and AM4 is formed on the insulating film IF1. In other words, this laminated structure is formed by repeating the formation process of the amorphous layers and the impurity particles sequentially three or more times. Between the amorphous layers AM1 and AM2, AM2 and AM3, and AM3 and AM4, the impurity particles GR are discretely arranged in the direction along the first main surface of the semiconductor substrate SB. A film thickness of each of the amorphous layers AM1 to AM4 is, for example, 2 nm.

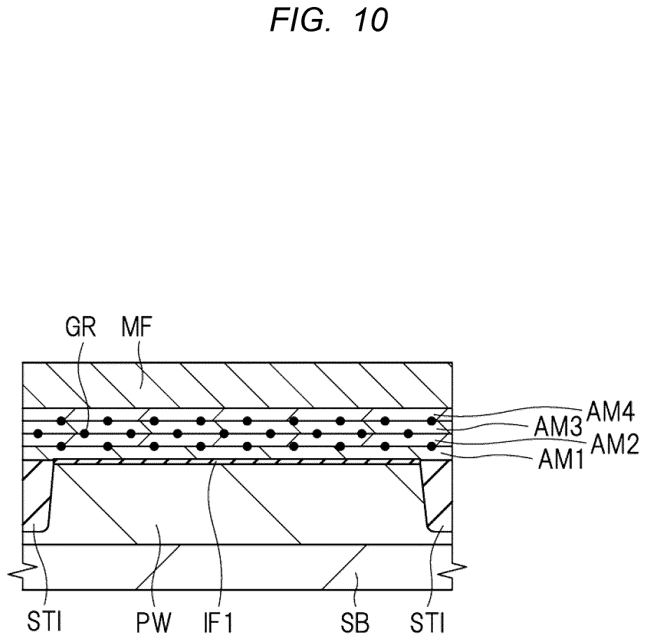

FIG. 10 illustrates a process of forming the metal film MF.

On top of the amorphous layer AM4, the metal film MF made of, for example, titanium nitride, tantalum nitride, or tungsten is formed using, for example, CVD or sputtering method. A thickness of the metal film MF is, for example, between 2 nm and 10 nm. The metal film MF is primarily provided to apply stress to the amorphous layers AM1 to AM44.

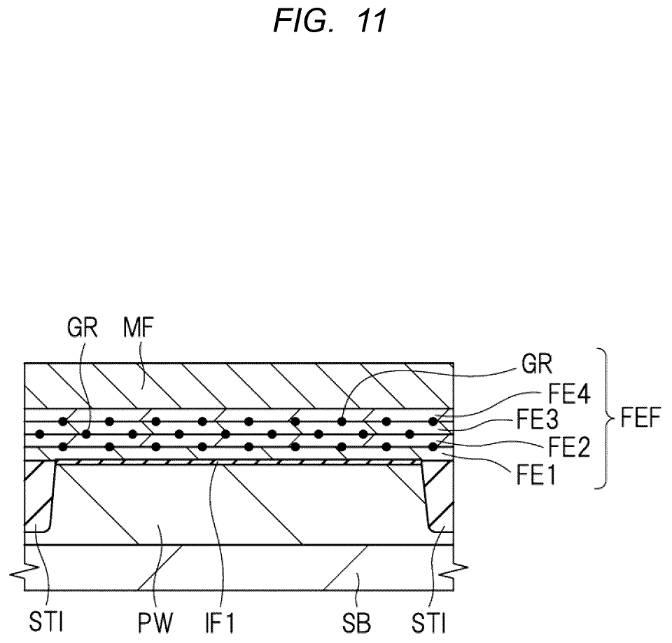

FIG. 11 shows a process of forming the ferroelectric layers FE1, FE2, FE3 and FE4, and the ferroelectric film FEF.

With the metal film MF formed on the amorphous layer AM4, the heat treatment (annealing) is performed. This crystallizes the amorphous layer AM1 to form the ferroelectric layer FE1, a tetragonal crystal, and crystallizes the amorphous layer AM2 to form the ferroelectric layer FE2, also a tetragonal crystal. Similarly, this heat treatment crystallizes the amorphous layer AM3 to form the ferroelectric layer FE3, and the amorphous layer AM4 to form the ferroelectric layer FE4, both tetragonal crystals. This heat treatment is carried out at a temperature of 500 to 700 degrees Celsius by, for example, RTA (Rapid Thermal Annealing) method. Through this heat treatment, the stacked structure including a plurality of amorphous layers crystallizes, forming the ferroelectric film FEF.

In this embodiment, the impurity particles GR are formed as a plurality of grains between the stacked amorphous layers. These grains function as crystal nuclei during the crystallization process. Through the above heat treatment, some of the grains, which are the impurity particles GR, combine with the substances contained in the amorphous layers AM1 and AM2 to form compounds. That is, after the heat treatment, the impurity particles GR are considered to be compounds formed by the combination of aluminum nitride, silicon, aluminum, carbon, nitrogen, hydrogen, or oxygen with hafnium or the aforementioned first element. The manner in which the amorphous layers crystallize around these crystal nuclei (crystal growth) due to the heat treatment will be described later.

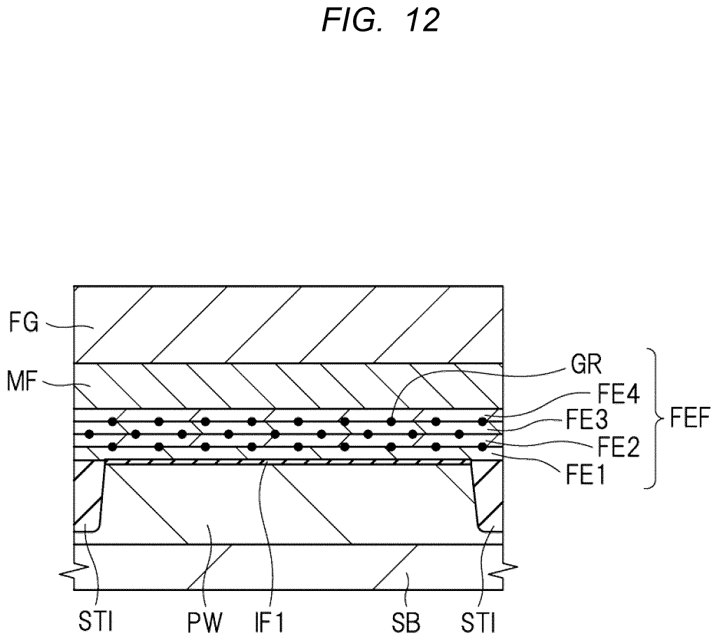

FIG. 12 shows a step of forming a conductive film FG.

On top of the metal film MF, the conductive film FG made of polycrystalline silicon with n-type impurities introduced is formed, for example, by CVD method. As mentioned above, if the ferroelectric film FEF can be sufficiently maintained as tetragonal crystals, the metal film MF may be removed before forming the conductive film FG.

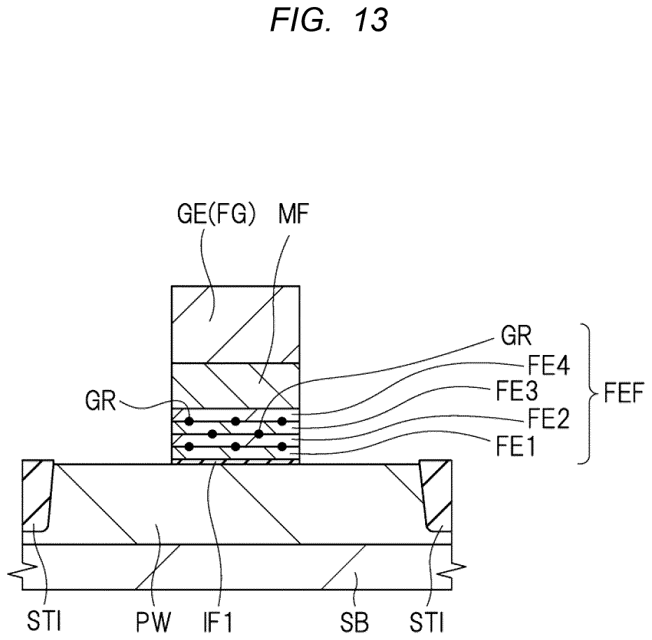

FIG. 13 shows a process of forming the gate electrode GE.

By photolithography and etching processes, the conductive film FG is patterned. This forms the gate electrode GE made of the conductive film FG. Subsequently, by performing an etching process, the metal film MF, the ferroelectric film FEF, and the insulating film IF1 not covered by the gate electrode GE is removed. Here, an example is given where the metal film MF is left under the gate electrode GE (conductive film FG), so the metal film MF functions as part of the gate electrode GE.

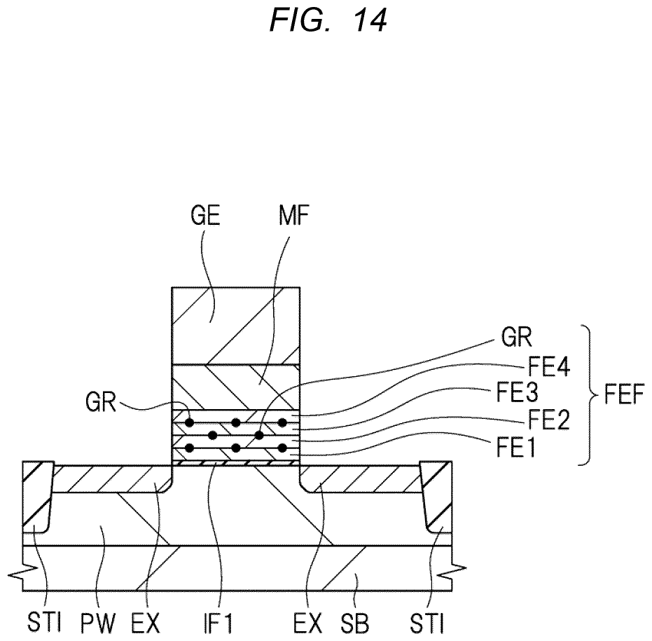

FIG. 14 shows a process of forming the extension region EX.

By photolithography and ion implantation, an n-type impurity region, the extension region EX, is formed within the well region PW at a position aligned with the gate electrode GE. The extension region EX constitutes part of the source region or part of the drain region of the ferroelectric memory cell.

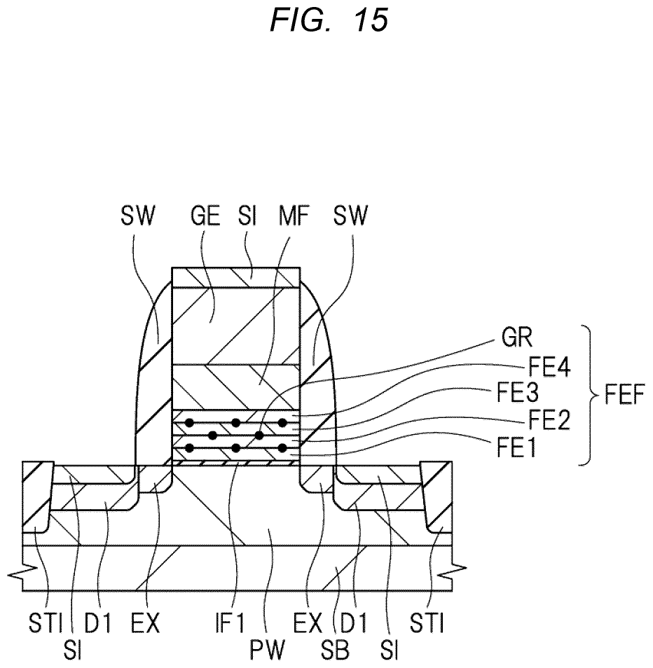

FIG. 15 shows a process of forming the sidewall spacer SW, the diffusion region D1, and the silicide layer SI.

First, for example, a silicon oxide film and a silicon nitride film are sequentially formed over the gate electrode GE, for example, by CVD. Next, the silicon nitride film is processed by anisotropic etching. Then, the silicon oxide film formed on the upper surface of the gate electrode GE is removed. As a result, the sidewall spacer SW, including a laminated film of silicon oxide and silicon nitride, is formed on the side surface of the gate electrode GE.

Next, by photolithography and ion implantation, the diffusion region D1, which is an n-type impurity region, is formed within the well region PW at a position aligned with the sidewall spacer SW. The diffusion region D1 has a higher impurity concentration than the extension region EX, connects to the extension region EX, and constitutes part of the source region or part of the drain region of the ferroelectric memory cell.

Next, a low-resistance silicide layer SI is formed on the upper surfaces of both the diffusion region D1 and the gate electrode GE by Salicide (Self Aligned Silicide) technique.

The silicide layer SI can be formed specifically as follows: First, a metal film for forming the silicide layer SI is formed on the semiconductor substrate SB to cover the diffusion region D1 and the gate electrode GE. This metal film includes, for example, cobalt, nickel, or a nickel-platinum alloy. Next, a first heat treatment at about 300 to 400 degrees Celsius and then a second heat treatment at about 600 to 700 degrees Celsius are applied to the semiconductor substrate SB to react materials contained in the diffusion region D1 and the gate electrode GE with the metal film. As a result, the silicide layer SI including cobalt silicide (CoSi2), nickel silicide (NiSi), or nickel-platinum silicide (NiPtSi) is formed on the upper surfaces of both the diffusion region D1 and the gate electrode GE. Subsequently, an unreacted metal film is removed.

Furthermore, if a metal film such as a titanium nitride film, an aluminum film, or a tungsten film, or a laminated film appropriately laminating these, is adopted as materials constituting the gate electrode GE, after the process of FIG. 15, the polysilicon film, which is a material of the gate electrode GE, can be replaced with the above metal film or the above laminated film using the so-called gate last process.

As a result, the ferroelectric memory cell with an MFIS structure is formed. That is, the ferroelectric memory cell comprises at least the insulating film IF1, the ferroelectric film FEF, and the gate electrode GE, and the pair of diffusion regions D1 that constitute part of the source region or part of the drain region.

Subsequently, the structure shown in FIG. 2 is obtained through the following steps.

First, the interlayer insulating film IL1, for example, made of silicon oxide, is formed over the ferroelectric memory cell by, for example, a CVD method. Next, using photolithography and etching processes, the plurality of contact holes are formed in the interlayer insulating film IL1. Then, the barrier metal film including, for example, a titanium film, a titanium nitride film, or a laminated film of these, is formed in these plurality of contact holes, and a conductive film primarily included tungsten is formed on the barrier metal film. Next, by removing the barrier metal film and the conductive film outside the contact holes, for example, by a CMP method, the plug PG is formed in the contact holes. The plug PG is electrically connected to the diffusion region D1 through the silicide layer SI. Although not shown in the figure, there also exists the plug PG that is electrically connected to the gate electrode GE.

### (Crystal Growth)

The ferroelectric memory cell operates at relatively low voltages, which is characterized by low power consumption. However, in structures composed of two ferroelectric layers, it has been difficult to form the ferroelectric memory cell that operate at even lower voltages, for example, below 4V. The difficulty in forming such a low-voltage ferroelectric memory cell is due to the crystallization of the ferroelectric layers occurring through isotropic crystal growth (3-dimensional nucleation).

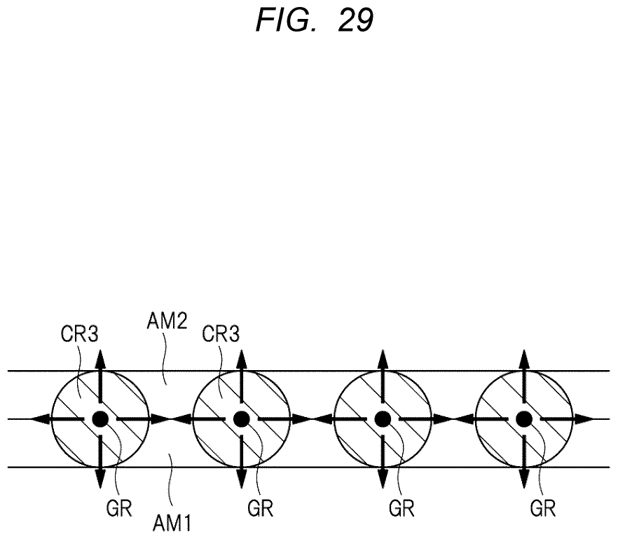

FIG. 29 shows a mode of crystal growth in the ferroelectric layer as a comparative example. As shown in FIG. 29, in the comparative example, the ferroelectric film is formed by crystallizing only two stacked amorphous layers AM1 and AM2. A film thickness of each of the amorphous layers AM1 and AM2 is, for example, 3 nm. The impurity particles GR are spaced apart and arranged between the amorphous layers AM1 and AM2. When these amorphous layers AM1 and AM2 are heat-treated, each of them crystallizes three-dimensionally around the impurity particles GR, which serve as a crystal nuclei CR3. In other words, the crystal nuclei CR3 expand spherically. Each crystal nucleus CR3 grows within each of the amorphous layers AM1 and AM2, centered around the impurity particles GR between them.

However, in this case, when the growing crystal nuclei CR3 collide, the crystal growth temporarily stops. As a result, gaps that cannot be crystallized form between the crystals, leaving amorphous regions (non-crystallized areas) in these gaps. Consequently, the density of crystals exhibiting ferroelectricity within the ferroelectric film becomes low. That is, due to the poor crystallinity of the ferroelectric film, it is difficult to reduce the operating voltage of the ferroelectric memory cell equipped with such the ferroelectric film.

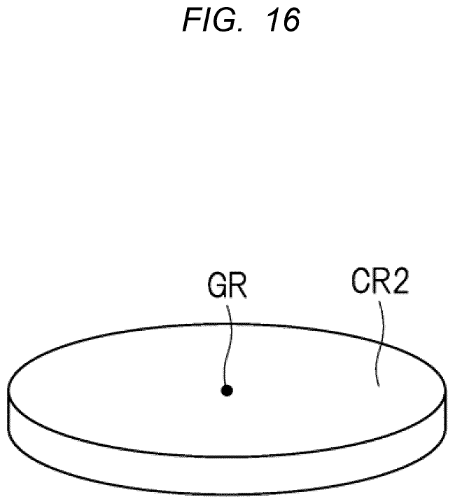

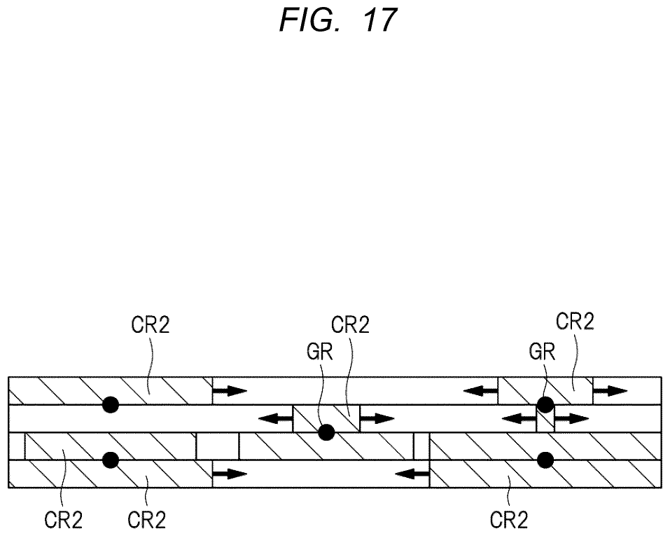

In contrast, the crystallization process in the present embodiment, namely the heat treatment process described in FIG. 11, suppresses the formation of the aforementioned gaps and improves the crystallinity of the ferroelectric film by causing crystal growth in the amorphous layer around the impurity particles GR in a horizontal direction, i.e., two-dimensionally, as shown in FIGS. 16 and 17. FIG. 16 is a perspective view explaining the mode of crystallization of the amorphous layer, and FIG. 17 is a cross-sectional view explaining the mode of crystallization of the amorphous layer. Note that the hatching of the amorphous layer is omitted in FIG. 17 for clarity.

Here, a crystal nucleus CR2 expands in a disc shape centered around the impurity particle GR, and its thickness essentially does not exceed the film thickness of each of the amorphous layers AM1 to AM4. The crystal nucleus CR2 expands only in the horizontal direction (lateral direction) within each of the amorphous layers, and the crystal growth temporarily stops when it collides with another crystal nucleus CR2. Therefore, the formation of the aforementioned gaps can be suppressed compared to the comparative example.

In the present embodiment, while the presence of three-dimensionally growing crystals is conceivable, two-dimensional nucleation predominates throughout the ferroelectric film. To ensure that two-dimensional nucleation predominates in crystal growth, a surface energy of the horizontal plane of the crystal grains of each of the amorphous layers is made lower than a surface energy of the vertical face of the crystal grains, and a film thickness of each of the amorphous layers is controlled within a certain range (here, 2 nm or less). This enables the expectation of epitaxial-like crystal growth. To reduce a surface energy of the horizontal plane of the crystal grains of each of the amorphous layers compared to a surface energy of the vertical plane of the crystal grains of each of the amorphous layers, it is sufficient to discretely control an arrangement of the impurity particles GR according to at least one of the following two conditions. That is, the surface density of the impurity particles GR is within a range of 1×10¹²/cm² to 1×10¹³/cm². Furthermore, the volume density of the impurity particles GR is within the range of 1×10¹⁸/cm³ to 1×10²¹/cm³. In addition, the average distance between the impurity particles GR in plan view is 2.5 nm or more and 11 nm or less. As in the comparative example of FIG. 29, there is a risk that three-dimensional nucleus growth becomes dominant with only two layers of amorphous layers, therefore, in the present embodiment, three or more layers of amorphous layers are formed.

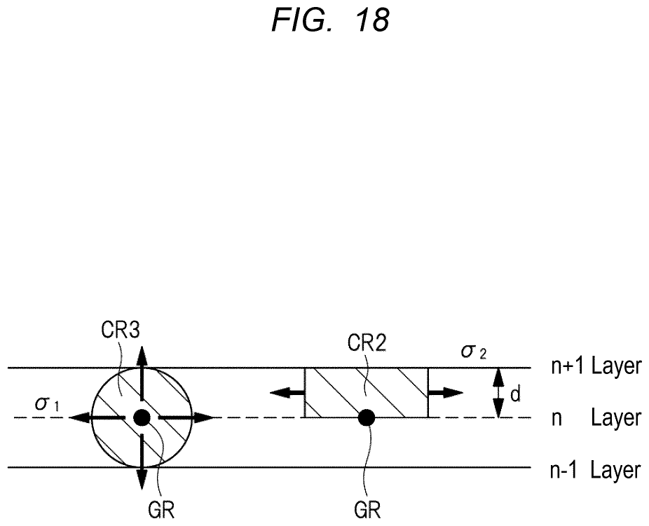

Next, using FIG. 18, a range of film thickness of the amorphous layer where two-dimensional nucleus growth becomes dominant is explained. In FIG. 18, the three-dimensional growing crystal nucleus CR3 is shown on the left side, and the two-dimensional growing crystal nucleus CR2 is shown on the right side. The boundaries of the amorphous layers AM1 and AM2 are shown with dashed lines. In the present embodiment where the crystal nucleus CR2 grows two-dimensionally, the amorphous layers AM3 and AM4 not shown are also provided above.

The “n−1 layer” shown on the right side of FIG. 18 refers to the bottom surface of the first amorphous layer AM1, the “n layer” refers to the bottom surface of the second amorphous layer AM2, and the “n+1 layer” refers to the upper surface of the second amorphous layer AM1 (or the bottom surface of the third amorphous layer AM3). d represents the thickness of each of the amorphous layers. σ₁ is a surface energy (unit: J/m²) within the n layer of the amorphous layer, and σ₂ is a surface energy (unit: J/m²) of each layer interface. Here, if the driving force for crystallization (unit: J/m²) is AG, the critical growth radius Rc(3D) of the three-dimensional growing crystal nucleus CR3 is expressed as Rc(3D)=2σ₁/ΔG>d. Furthermore, the critical growth radius Rc(2D) of the two-dimensional growing crystal nucleus CR2 is expressed as Rc(2D)=dσ₁/(dΔG−2σ₂).

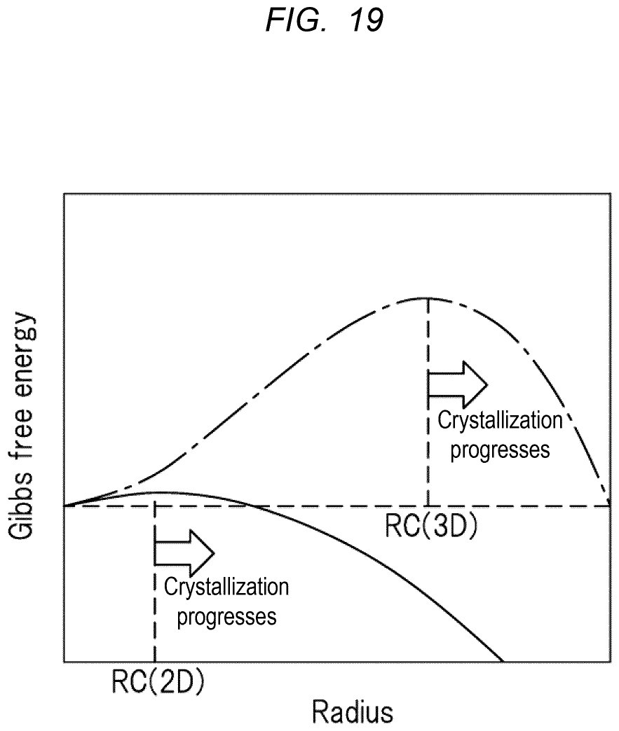

The relationship between the radius of the crystal and the driving energy of the crystal is represented by the graph shown in FIG. 19. The horizontal axis of the graph in FIG. 19 is the radius of the crystal, and the vertical axis is the Gibbs free energy (driving energy) of the crystal. In FIG. 19, the graph during the formation of the three-dimensional nucleus growth (crystal nucleus CR3) is shown with a dotted line, and the graph during the formation of the two-dimensional nucleus growth (crystal nucleus CR2) is shown with a solid line. As shown in FIG. 19, the critical growth radius Rc(2D) of the two-dimensional growing crystal nucleus CR2 is smaller than the critical growth radius Rc(3D) of the three-dimensional growing crystal nucleus CR3. In other words, when both crystal nuclei CR3 and CR2 start to crystallize and their radius gradually increases, the crystallization of the crystal nucleus CR2 begins while its radius is still small, and when crystallization is completed, the crystal nucleus CR2 becomes larger and dominant over the crystal nucleus CR3. σ2 represents wettability, and its value depends on the amount of the impurity particles GR added and the surface treatment of the amorphous layer.

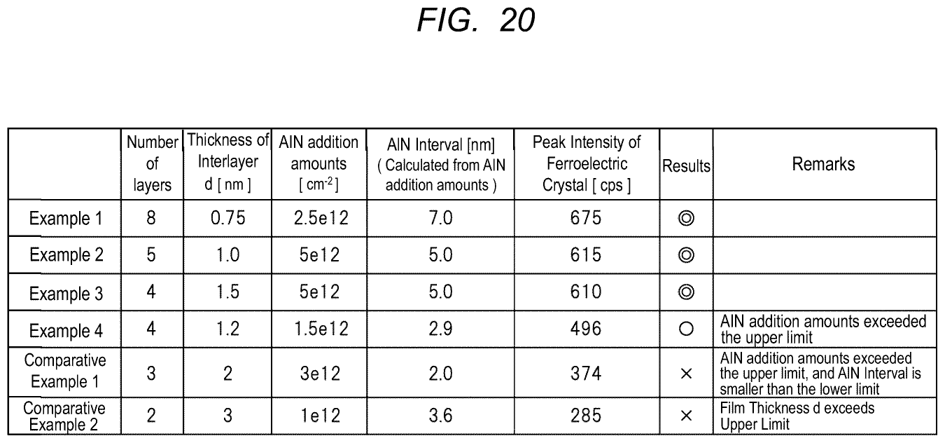

The table in FIG. 20 shows the results of experiments conducted by the inventors to explore methods to reduce the surface energy σ₂. In these experiments, aluminum nitride is used as the impurity particles, but a mixture of silicon and aluminum may also be used instead. Here, aluminum nitride impurity particles are discretely added to the upper surface of the amorphous layer, and the doping is conducted within the range of 1×10¹²/cm² to 1×10¹³/cm². Furthermore, the volume density of the impurity particles is within the range of 1×10¹⁸/cm³ to 1×10²¹/cm³, and the average distance between the impurity particles in a plan view is between 2.5 nm and 11 nm. In Examples 1 to 4 and Comparative Examples 1 and 2 shown in the table, the film thickness of the amorphous layer is set from the lattice constant of the crystalline material (0.5 nm or more) to the surface tension determined by the material properties (2 nm or more). However, some Examples or Comparative Examples are conducted under conditions that deviate from these upper and lower limits.

In this experiment, a crystal peak intensity of 600 or more is rated as excellent (double circle), 400 or more but less than 600 as pass (circle), and less than 400 as fail. As a result, Comparative Examples 1 and 2 are rated as fail. The reason for the failure of Comparative Example 1 is considered to be that the amount of added aluminum nitride exceeds the upper limit, and the spacing of aluminum nitride is smaller than the lower limit. The reason for the failure of Comparative Example 2 is considered to be that the film thickness d exceeds the upper limit. The low crystal peak intensity of Examples 4 is considered to be due to the amount of added aluminum nitride exceeding the upper limit. Therefore, it is desirable to set the surface density of the impurity particles within the range of 1×10¹²/cm² to 1×10¹³/cm², the volume density within the range of 1×10¹⁸/cm³ to 1×10²¹/cm³, and the average distance between the impurity particles in a plan view to be between 2.5 nm and 11 nm.

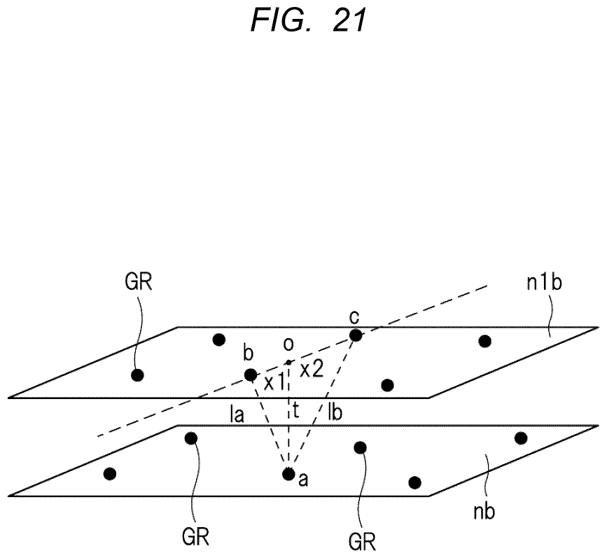

FIG. 21 shows the arrangement of the impurity particles. In the perspective view of FIG. 21, the bottom surface nb of the n-layer of the ferroelectric layer and the bottom surface nib of the (n+1)-layer of the ferroelectric layer are shown as rectangular areas, respectively. Within these surfaces, the impurity particles GR are discretely arranged. Here, the point (position) of a certain impurity particle GR on the bottom surface nb of the n-layer is denoted as a, and the points (positions) of two certain impurity particles GR on the bottom surface nib of the (n+1) layer are denoted as b and c, respectively. Also, the point (position) directly above position a on the bottom surface nib of the (n+1) layer is denoted as o. The amount of added impurity particles GR is D. The distance between the impurity particles GR is R, and the thickness of the amorphous layer, that is, the distance between the bottom surface nb of the n-layer of the ferroelectric layer and the bottom surface nib of the (n+1)-layer of the ferroelectric layer, is t.

At this time, t is the distance between point a and point o. Also, the distance between point o and point b is x1, the distance between point o and point c is x2, the distance between point a and point b is la, and the distance between point a and point c is lb. At this time, x1+x2≈2R, and R≈(Dπ)^{-1/2}, where π is the pi constant. In this embodiment, by setting x1≤x2, it is ensured that t≤2R and t≤la≤lb for the arrangement of the impurity particles GR. Although points b and c are shifted from directly above point a in FIG. 21, the condition is still met even if point b is directly above point a. To meet this condition, in this embodiment, the surface density of the impurity particles GR is set within the range of 1×10¹²/cm² to 1×10¹³/cm², and the volume density is set within the range of 1×10¹⁸/cm³ to 1×10²¹/cm³.

Furthermore, the average distance between the impurity particles in a plan view is set to be no less than 2.5 nm and no more than 11 nm. Additionally, the range of t is set to be no less than 0.5 nm and no more than 2 nm.

### Effect of the First Embodiment

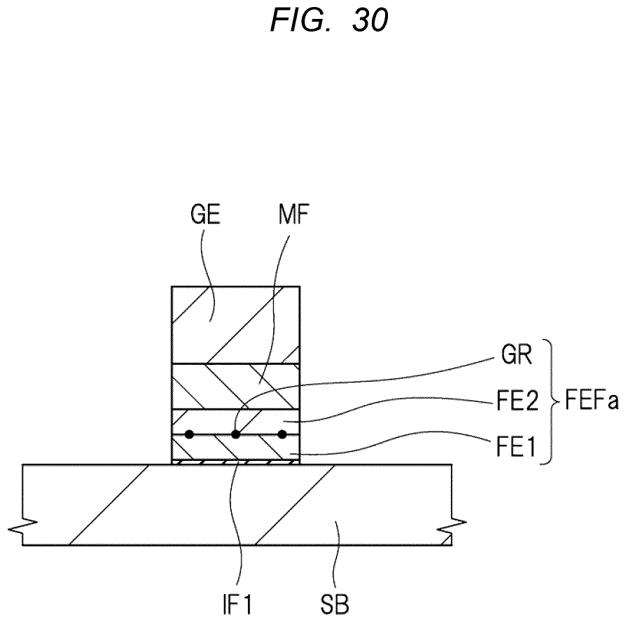

FIG. 30 shows a cross-sectional view of the main part of the ferroelectric memory cell, which is a comparative example. As shown in FIG. 30, the ferroelectric film FEFa of the ferroelectric memory cell in the comparative example is a laminated body, and the ferroelectric layers constituting this laminated body are only ferroelectric layers FE1 and FE2. The impurity particles GR are arranged between the ferroelectric layers FE1 and FE2. Within a ferroelectric film FEFa, as explained using FIG. 29, crystals grow three-dimensionally around the impurity particles GR.

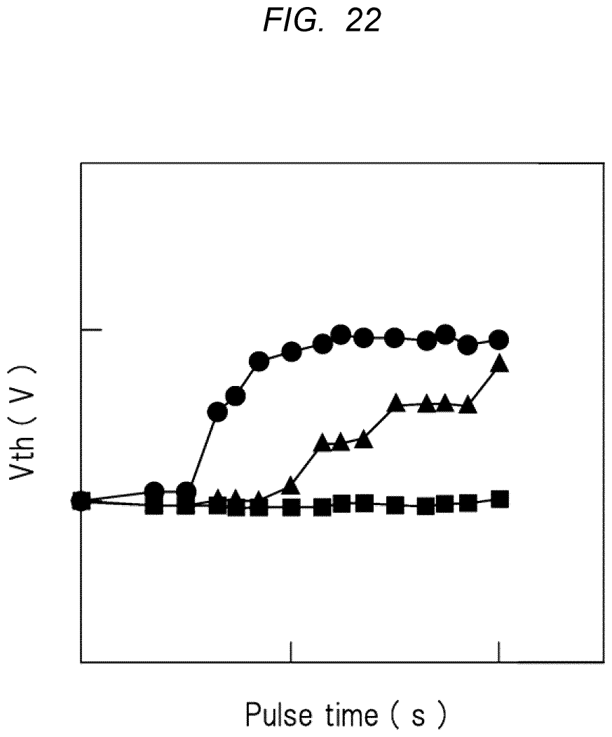

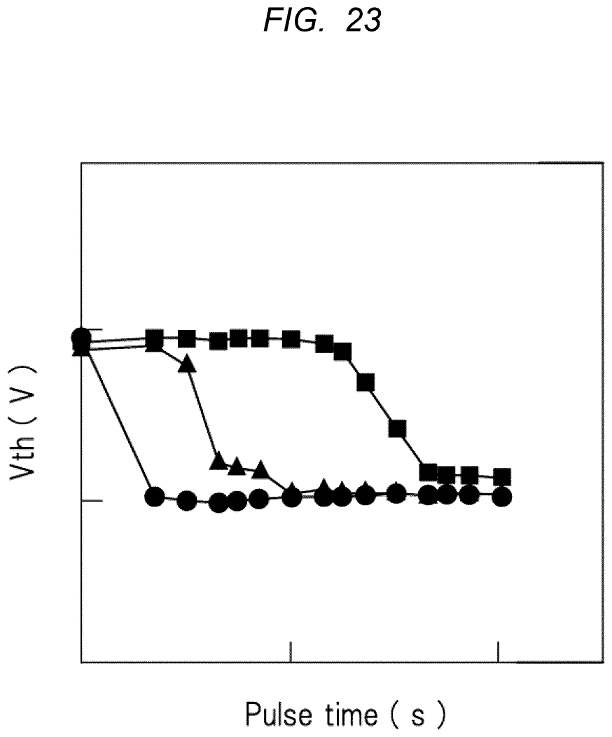

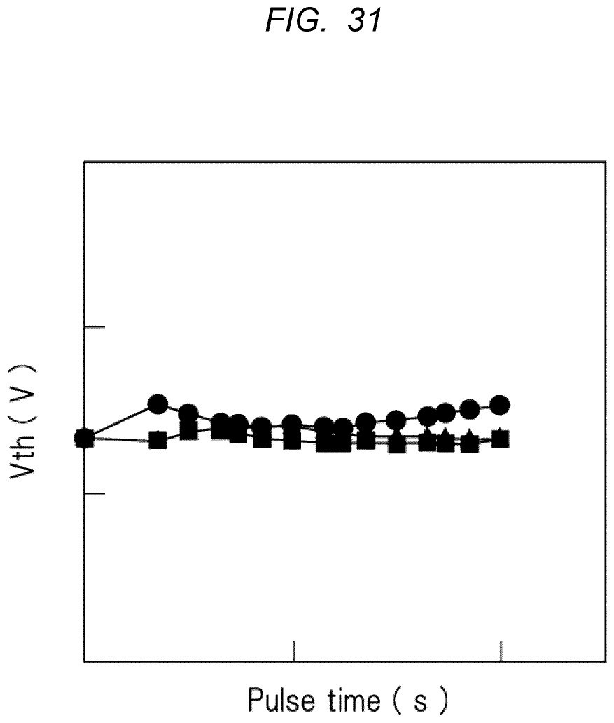

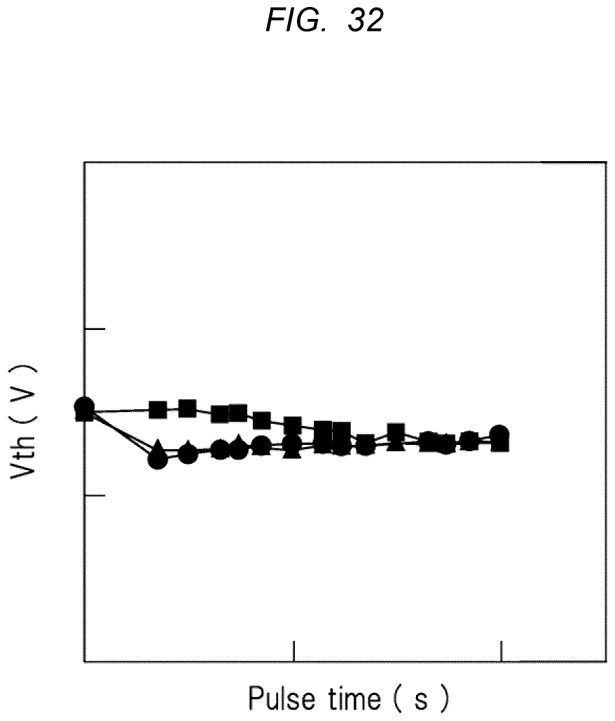

The write characteristics of the ferroelectric memory cell in such a comparative example are shown in the graph of FIG. 31, and the erase characteristics are shown in the graph of FIG. 32. The write characteristics of the main part of the ferroelectric memory cell of the present embodiment are shown in the graph of FIG. 22, and the erase characteristics are shown in the graph of FIG. 23. The horizontal axes in FIGS. 22, 23, 31, and 32 each represent the time during which voltage is applied to the ferroelectric memory cell, and the vertical axes represent the threshold voltage of the ferroelectric memory cell. In FIGS. 22 and 31, the graphs when −4V is applied to the gate electrode are shown with plots of black circles, when −3V is applied with plots of triangular circles, and when −2V is applied with plots of square circles. In FIGS. 23 and 32, the graphs when +4V is applied to the gate electrode are shown with plots of black circles, when +3V is applied with plots of triangular circles, and when +2V is applied with plots of square circles.

From FIG. 31, it can be seen that in the write operation of the ferroelectric memory cell of the comparative example, when −4V to −2V are applied to the gate electrode, there is hardly any difference in the threshold voltage in any case, indicating that the switching on and off of the current flow in the device is not occurring. Similarly, from FIG. 32, it can be seen that in the erase operation of the ferroelectric memory cell of the comparative example, when +4V to +2V are applied to the gate electrode, there is hardly any difference in the threshold voltage in any case, indicating that the switching on and off of the current flow in the device is not occurring. Thus, the ferroelectric memory cell of the comparative example cannot be driven at low voltages of 4V or less.

In contrast, as shown in FIG. 22, during the write operation of the ferroelectric memory cell of the present embodiment, by applying −4V or −3V to the gate electrode, the threshold voltage increases and writing is performed. Also, as shown in FIG. 23, during the erase operation of the ferroelectric memory cell of the present embodiment, by applying +4V to +2V to the gate electrode, the threshold voltage decreases and erasure is performed. That is, in the present embodiment, compared to the comparative example, the operating voltage of the ferroelectric memory cell can be reduced. Specifically, a memory operating voltage in the ferroelectric memory cell (semiconductor element) is reduced to 4V or less. This is an effect due to the improvement of the crystallinity of the ferroelectric film in the present embodiment.

By suppressing the memory operating voltage, there is no need to modulate a power supply voltage for memory operation. Therefore, a semiconductor device equipped with a circuit that performs the write and erase operations in the ferroelectric memory cell without modulating the power supply voltage supplied to the ferroelectric memory cell can be realized.

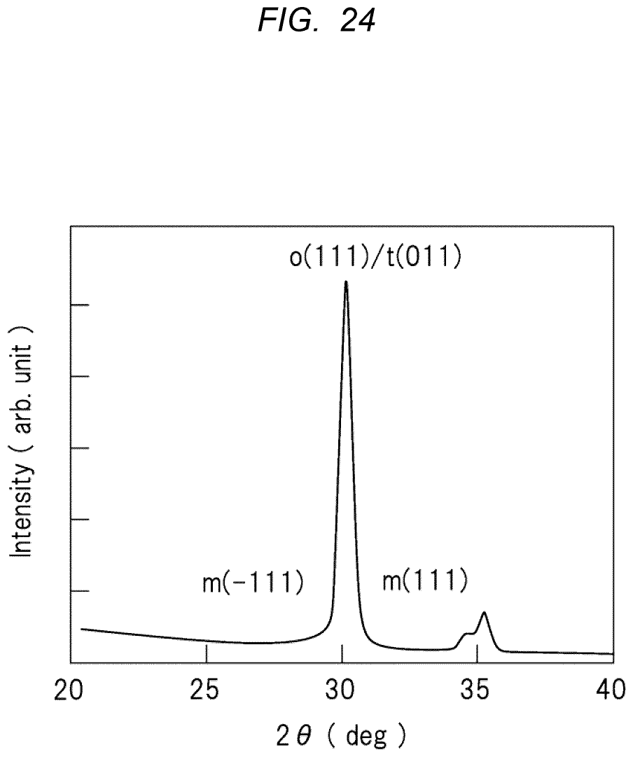

FIG. 24 shows the results of X-ray diffraction in the ferroelectric film. The horizontal axis of the graph shown in FIG. 24 represents the angle (incident angle of the X-ray beam), and the vertical axis represents the scattering intensity of the X-rays. By irradiating the ferroelectric film of the present embodiment with an X-ray beam and measuring its scattering intensity, it was found that the orthorhombic phase (o(111)) is predominantly present compared to the monoclinic phase (m(111)). The predominant presence of the orthorhombic phase enables an increase in the residual polarization of the ferroelectric film, improvement in the performance as a ferroelectric, and reduction in the driving power of the ferroelectric memory cell.

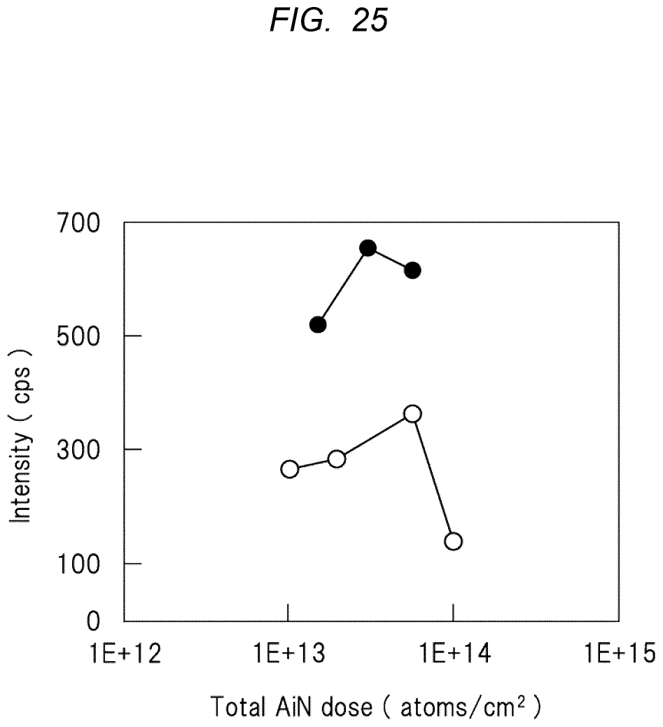

FIG. 25 shows the crystal peak intensity of the orthorhombic phase (111) in a graph. The horizontal axis of FIG. 25 represents the addition amount (dose amount) of aluminum nitride, which is an impurity particle, and the vertical axis represents the crystal peak intensity (physical strength). The graph indicated by white circles plots the case where the ferroelectric layer is formed in only two layers, as shown in the comparative example in FIG. 30. The graph indicated by black circles plots the case where the ferroelectric layer is formed in four layers, as in the present embodiment. From FIG. 25, it can be seen that the crystal peak intensity of the orthorhombic phase of the ferroelectric film increases when more than two layers of the ferroelectric layer are formed, compared to the comparative example.

Therefore, in the present embodiment, the ferroelectricity of the ferroelectric film FEF (see FIG. 2) is improved, and the ferroelectric memory cell capable of operating at low voltage can be realized. In other words, the performance of semiconductor devices can be improved.

### Second Embodiment

In the first embodiment, the impurity particles are discretely arranged, and more than three layers of ferroelectric (amorphous) layers are provided. In the first embodiment, a crystal is grown two-dimensionally using the impurity particles as nuclei. In contrast, crystals can be grown two-dimensionally even if three or more amorphous layers are provided and the surface (upper surface) of each amorphous layer is subjected to hydrophilic treatment. In the following, in this embodiment, a method of growing crystals two-dimensionally by hydrophilizing the surface of an amorphous layer without arranging multiple impurity particles will be described.

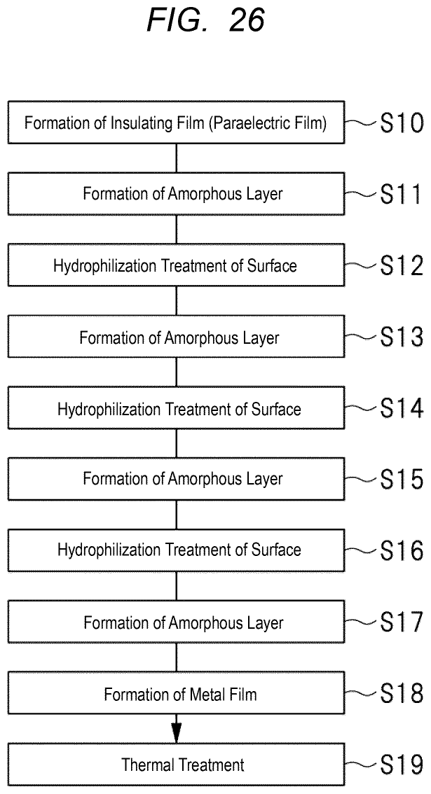

FIG. 26 illustrates the flow of processes up to a heat treatment after forming the insulating film IF1, amorphous layers AM1, AM2, AM3 and AM4, and a metal film MF on a semiconductor substrate in the manufacturing method of the semiconductor device of this embodiment. The film formation process in this series of processes is similar to the process described using FIGS. 5, 8, 9, 10, and 11, but without the addition of the impurity particles GR. However, after forming each of the amorphous layers AM1, AM2, and AM3, the surface of each of the amorphous layers is hydrophilized.

That is, as shown in FIG. 26, a formation of the insulating film IF1 (Step S10), a formation of the amorphous layer AM1 (Step S11), a hydrophilization treatment of a surface of the amorphous layer AM1 (Step S12) and a formation of the amorphous layer AM2 (Step S13) are performed. Subsequently, a hydrophilization of the surface of the amorphous layer AM2 (Step S14), a formation of the amorphous layer AM3 (Step S15), a hydrophilization treatment of a surface of the amorphous layer AM3 (Step S16), and a formation of the amorphous layer AM4 (Step S17) are performed. Then, a formation of the metal film MF (Step S18) and a crystallization by a heat treatment (Step S19) are performed. A thickness of each of the insulating film IF1, the amorphous layers AM1 to AM4, and the metal film MF, as well as the temperature conditions of the heat treatment, are the same as in the first embodiment. This forms a stacked structure including the amorphous layers AM1 to AM4. Here, the stacked structure is formed by repeating the formation process of the amorphous layer and the hydrophilization more than three times in sequence.

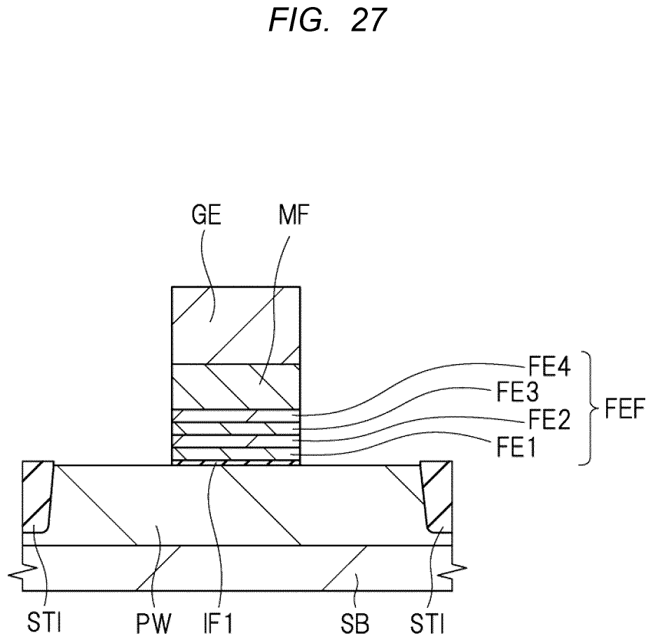

Subsequently, by performing the process described using FIGS. 12 and 13, the structure shown in FIG. 27 is obtained. As shown in FIG. 27, a ferroelectric film FEF comprises four layers of ferroelectric layers FE1 to FE4, but the impurity particles are not formed between the overlapping the ferroelectric layers. The surfaces (upper surfaces) of the ferroelectric layers FE1 to FE3 are hydrophilized.

The hydrophilization in Step S12 increases the wettability of the surface of the amorphous layer AM1. That is, it reduces a surface energy of the amorphous layer AM1. Similarly, the hydrophilization in Step S14 reduces a surface energy of the amorphous layer AM2, and the hydrophilization in Step S16 reduces the surface energy of the amorphous layer AM3. The surface energy of a hydrophilized amorphous layer is lower than that of the amorphous layer before hydrophilization. In other words, a contact angle of the hydrophilized amorphous layer is smaller than a contact angle of the amorphous layer before hydrophilization. In this manner, the interface between overlapping amorphous layers in a thickness direction is hydrophilized, promoting two-dimensional nucleation, i.e., crystal growth in a horizontal direction during the crystallization process of step S19. After obtaining the structure shown in FIG. 27, a ferroelectric memory cell, which is a semiconductor device of this embodiment, is formed by performing the processes described using FIGS. 14 and 15.

The hydrophilization treatment specifically refers to a process performed on the surface of the amorphous layer, involving either O2 plasma treatment, O3 treatment, APM (Ammonia-hydrogen Peroxide Mixture) cleaning, HPM (Hydrochloric acid-hydrogen Peroxide Mixture) cleaning, water rinse, UV (Ultraviolet) treatment, exposure to the atmosphere, or a combination thereof. For example, the hydrophilization treatment can be carried out by sequentially performing cleaning with a mixed solution of sulfuric acid and hydrogen peroxide water followed by rinsing with pure water on the semiconductor substrate on which the amorphous layer has been formed. Furthermore, the hydrophilization treatment can be performed by attaching hydroxyl groups to the hydrophilization target surface by treating the semiconductor substrate on which the amorphous layer has been formed with hydrofluoric acid followed by rinsing with running pure water.

Additionally, the hydrophilization treatment can be performed by thermally oxidizing the amorphous layer containing silicon to form a silicon oxide film on the surface of the amorphous layer, or by reacting the amorphous layer with ammonia to form a silicon nitride film on the surface of the amorphous layer. Moreover, the hydrophilization treatment can be carried out by immersing the semiconductor substrate on which the amorphous layer has been formed in a solution of H2SO4:H2O2=1:4. Also, the hydrophilization treatment can be performed by cleaning the semiconductor substrate on which the amorphous layer has been formed with nitric acid and hydrogen peroxide.

Furthermore, the hydrophilization treatment can be carried out by ashing the surface of the semiconductor substrate on which the amorphous layer has been formed with oxygen plasma and then immersing it in water. Additionally, the hydrophilization treatment can be performed by treating the semiconductor substrate on which the amorphous layer has been formed with ozone using ultraviolet light. Moreover, the hydrophilization treatment can be carried out by treating the semiconductor substrate on which the amorphous layer has been formed with a surface treatment liquid selected from organic solvents containing hydroxyl groups and aqueous solutions with pH 1 to 10.

The methods of hydrophilization are not limited to these, and may also be performed by irradiating the amorphous layer with energy rays or using a dry process such as RIE (Reactive Ion Etching).

In this embodiment, by stacking more than three amorphous layers and performing hydrophilization treatment on the interface between the overlapped amorphous layers, it is possible to grow crystals two-dimensionally within each of the amorphous layers during subsequent heat treatment. As a result, the crystallinity of the ferroelectric film can be enhanced, thereby improving the performance of the semiconductor device.

### Third Embodiment

The first and second embodiments described above may be combined with each other. This embodiment involves both forming impurity particles discretely on the upper surface of an amorphous layer after forming the amorphous layer and performing hydrophilization treatment on the surface of the amorphous layer.

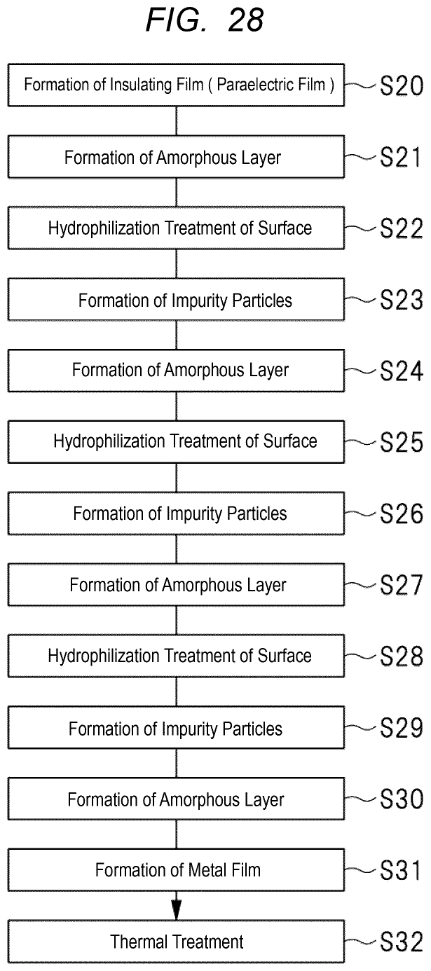

FIG. 28 illustrates the process up to a heat treatment after forming the insulating film IF1, amorphous layers AM1, AM2, AM3 and AM4, and a metal film MF on a semiconductor substrate in the manufacturing method of the semiconductor device of the present embodiment. This series of processes includes the formation of the amorphous layers AM1, AM2, and AM3, followed by hydrophilization treatment and the formation of the impurity particles, in addition to the processes described using FIGS. 5 to 11.

That is, as shown in FIG. 28, a formation of the insulating film IF1 (Step S20), a formation of the amorphous layer AM1 (Step S21), a hydrophilization treatment of the surface of the amorphous layer AM1 (Step S22), a formation of the impurity particles (Step S23), and a formation of the amorphous layer AM2 (Step S24) are performed. Subsequently, a hydrophilization treatment of a surface of the amorphous layer AM2 (Step S25), a formation of the impurity particles (Step S26), a formation of the amorphous layer AM3 (Step S27), a hydrophilization treatment of a surface of the amorphous layer AM3 (Step S28), a formation of the impurity particles (Step S29), and a formation of the amorphous layer AM4 (Step S30) are performed. After that, a formation of the metal film MF (Step S31) and a crystallization by a heat treatment (Step S32) are performed. The film thickness of the insulating film IF1, the amorphous layers AM1 to AM4, and the metal film MF, as well as the temperature conditions of the heat treatment, are the same as in the first embodiment. Thus, a laminated structure including the amorphous layers AM1 to AM4 is formed. Here, the laminated structure is formed by repeating the formation process of the amorphous layer, the hydrophilization treatment, and the formation process of the impurity particles three or more times in sequence.

The hydrophilization treatment in Step S22 and the formation process of the impurity particles in Step S23 each increase the wettability of the surface of the amorphous layer AM1. That is, they reduce the surface energy of the amorphous layer AM1. Similarly, the hydrophilization treatment in Step S25 and the formation process of the impurity particles in Step S26 each reduce the surface energy of the amorphous layer AM2, and the hydrophilization treatment in Step S28 and the formation process of the impurity particles in Step S29 each reduce the surface energy of the amorphous layer AM3. In this way, the interfaces between the overlapping amorphous layers in the thickness direction are hydrophilized, and the two-dimensional nucleation of crystals in the crystallization process of Step S29 is promoted using the impurity particles as nuclei. After the heat treatment in Step S32, a ferroelectric memory cell, which is the semiconductor device of the present embodiment, is formed by performing the processes described using FIGS. 12 to 15.

In this embodiment, more than three layers of amorphous layers are stacked, and after placing the impurity particles on the surface of the amorphous layers, hydrophilization treatment of the interfaces between the overlapping amorphous layers is performed. Therefore, the two-dimensional growth of crystals within each amorphous layer during subsequent heat treatment can be promoted more than in Embodiments 1 and 2. As a result, the crystallinity of a ferroelectric film can be enhanced, thereby improving the performance of the semiconductor device.

Although the invention made by the present inventor has been specifically described based on the embodiment, the present invention is not limited to the as described above embodiment, and it is needless to say that various modifications can be made without departing from the gist thereof.

For instance, similar to the first embodiment, in the second and third embodiments, controlling the thickness of the amorphous layer is important to favor the two-dimensional growth of crystals within the ferroelectric film.

Furthermore, a part of the content described in the embodiments is listed below.

### Appendix 1

A semiconductor device comprising:
a semiconductor element includes
a paraelectric film formed on a semiconductor substrate, and
a laminated film formed on the paraelectric film, wherein
the laminated film includes a plurality of ferroelectric layers stacked in three or more layers, and
the semiconductor element is a memory element having the plurality of ferroelectric layers, and
a memory operating voltage on the semiconductor element is 4V or less.

### Appendix 2

The semiconductor device according to Appendix 1 further comprising:
a circuit performing a write operation and an erase operation in the semiconductor element without modulating a power supply voltage.

What is claimed is:

1. A semiconductor device comprising:
a paraelectric film formed on a semiconductor substrate, and
a laminated film formed on the paraelectric film, wherein
the laminated film includes a plurality of ferroelectric layers laminated in three or more layers.

2. The semiconductor device according to claim 1, wherein
each of surfaces of the plurality of ferroelectric layers has impurity particles discretely.

3. The semiconductor device according to claim 1, wherein
a thickness of each of the plurality of ferroelectric layers is 0.5 nm or more and 2 nm or less.

4. The semiconductor device according to claim 1, wherein
a thickness of the laminated film is 6 nm or more and 20 nm or less.

5. The semiconductor device according to claim 1, wherein
each of the plurality of ferroelectric layers is made of materials containing a metal oxide and a first element,
the metal oxide is hafnium oxide or gallium oxide, and
the first element is any of zirconium, silicon, germanium, yttrium, lanthanum or ytterbium.

6. The semiconductor device according to claim 2, wherein
the paraelectric film is a silicon oxide film or a silicon oxynitride film.

7. The semiconductor device according to claim 2, wherein
the impurity particles are any of aluminum nitride, silicon, aluminum, carbon, nitrogen, hydrogen, or oxygen, or a combination thereof.

8. The semiconductor device according to claim 2, wherein
a surface density of the impurity particles is 1×10¹²/cm² or more and 1×10¹³/cm² or less.

9. The semiconductor device according to claim 2, wherein
a volume density of the impurity particles is 1×10¹⁸/cm³ or more and 1×10²¹/cm³ or less.

10. The semiconductor device according to claim 2, wherein
an average distance between each of the impurity particles in plan view is 2.5 nm or more and 11 nm or less.

11. The semiconductor device according to claim 1, wherein
each of the surfaces of the plurality of ferroelectric layers is hydrophilized.

12. The semiconductor device according to claim 11, wherein
a surface energy of the ferroelectric layer after hydrophilized is small than a surface energy of the ferroelectric layer before hydrophilized.

13. A manufacturing method of a semiconductor device, comprising:
(a) forming a paraelectric film on a semiconductor substrate,
(b) forming a laminated structure on the paraelectric film,
(c) forming a metal film on the laminated structure, and
(d) after the step of (c), performing a heat treatment, wherein
the step of (d) is a laminated structure forming step by repeating the following steps at least three times in this order,
(b1) forming an amorphous layer including materials containing a metal oxide and a first element,
(b2) discretely providing impurity particles on a surface of the amorphous layer, and
the step of (d) is a ferroelectric laminated film forming step by crystallizing the amorphous layers of the laminated structure in a horizontal direction.

14. The manufacturing method of the semiconductor device according to claim 13, wherein
a thickness of each of the amorphous layers of the laminated structure is 0.5 nm or more and 2 nm or less.

15. The manufacturing method of the semiconductor device according to claim 13, wherein
the metal oxide is hafnium oxide or gallium oxide, and
the first element is any of zirconium, silicon, germanium, yttrium, lanthanum or ytterbium.

16. The manufacturing method of the semiconductor device according to claim 13, wherein
a surface density of the impurity particles provided in the step of (b2) is 1×10¹²/cm² or more and 1×10¹³/cm² or less.

17. The manufacturing method of the semiconductor device according to claim 13, wherein
an average distance between each of the impurity particles in plan view is 2.5 nm or more and 11 nm or less.

18. A manufacturing method of a semiconductor device, comprising:
(a) forming a paraelectric film on a semiconductor substrate,
(b) forming a laminated structure on the paraelectric film,
(c) forming a metal film on the laminated structure, and
(d) after the step of (c), performing a heat treatment, wherein
wherein
the step of (b) is a laminated structure forming step by repeating the following steps at least three times in this order,
(b1) forming an amorphous layer including materials containing a metal oxide and a first element,
(b2) hydrophilizing a surface of the amorphous layer, and
the step of (d) is a ferroelectric laminated film forming step by crystallizing the amorphous layers of the laminated structure in a horizontal direction.

19. The manufacturing method of the semiconductor device according to claim 18, wherein
in the step of (b2), a surface energy of the amorphous layer after hydrophilized is small than a surface energy of the amorphous layer before hydrophilized.

20. The manufacturing method of the semiconductor device according to claim 18, wherein
in the step of (b2), a contact angle of the amorphous layer after hydrophilized is small than a contact angle of the amorphous layer before hydrophilized.

21. The manufacturing method of the semiconductor device according to claim 18, wherein
the hydrophilization performed in the step of (b2) is any of O2 plasma treatment, O3 treatment, APM cleaning, HPM cleaning, water washing treatment, UV treatment, exposure to an atmosphere, or a combination thereof.

22. The manufacturing method of the semiconductor device according to claim 18, wherein
a thickness of each of the amorphous layers of the laminated structure is 0.5 nm or more and 2 nm or less.

23. The manufacturing method of the semiconductor device according to claim 18, wherein
the metal oxide is hafnium oxide or gallium oxide, and
the first element is any of zirconium, silicon, germanium, yttrium, lanthanum or ytterbium.

24. The manufacturing method of the semiconductor device according to claim 18, the step of (d) further including:
(b3) after the step of (b2), discretely providing impurity particles on a surface of the amorphous layer.
